(19) United States
(12) Patent Application Publication
(10) Pub. No.: US 2026/0168883 A1
(43) Pub. Date: Jun. 18, 2026

(54) METHOD AND SYSTEM OF DETERMINING FIELD DEPENDENT ABERRATIONS

(71) Applicants: Carl Zeiss SMT GmbH, Oberkochen (DE); ASML Netherlands B.V., Veldhoven (NL)

(72) Inventors: Edwin BOON, Veldhoven (NL); Sebastian FUCHS, Oberkochen (DE); Joachim FISCHBACH, Oberkochen (DE); Toralf GRUNER, Oberkochen (DE)

(21) Appl. No.: 19/529,767

(22) Filed: Feb. 4, 2026

Related U.S. Application Data
(63) Continuation of application No. PCT/EP2024/070249, filed on Jul. 17, 2024.

(30) Foreign Application Priority Data
Aug. 4, 2023 (DE) 10 2023 120 807.1

(51) Int. Cl. G01M 11/02; G03F 7/00

(52) U.S. Cl. CPC G01M 11/0264; G03F 7/706

(57) ABSTRACT

A method of determining field-dependent aberrations in an image field of an optical imaging system: defining a target grid comprising a plurality of target field points in the image field, wherein a target field point is a field point for which a level of aberration is to be determined; defining a measuring grid comprising a first subset of the target field points comprising all field points for which a level of aberration is to be determined in a measuring operation; measuring aberrations at all field points of the measuring grid to generate measured aberration data; defining an auxiliary grid comprising a second subset of the target field points comprising selected target field points not included in the measuring grid for which a level of aberration is to be determined in an aberration data generating operation.

### CROSS REFERENCE TO RELATED APPLICATIONS

This is a Continuation of International Application PCT/EP2024/070249, which has an international filing date of Jul. 17, 2024, and the disclosure of which is incorporated in its entirety into the present Continuation by reference. This Continuation also claims foreign priority under 35 U.S.C. § 119 (a)-(d) to and also incorporates by reference, in its entirety, German Patent Application DE 10 2023 120 87.1 filed on Aug. 4, 2023.

### FIELD

The techniques of this disclosure relate to a method of determining field-dependent aberrations of an optical imaging system. The optical imaging system may be configured as a projection lens of a projection exposure system for microlithography.

### BACKGROUND

Microlithographic projection exposure methods and systems are used predominantly for producing semiconductor components and other finely patterned components. These methods involve the use of masks (photomasks, reticles) or other patterning elements that bear or form the pattern of a structure to be imaged, for example, a line pattern of a layer of a semiconductor component. The pattern is positioned in a projection exposure system in the beam path between an illumination system and a projection lens such that the pattern lies in the region of the object plane of the projection lens. The projection lens is an optical imaging system. A substrate to be exposed, for example a semiconductor wafer coated with a radiation-sensitive layer (resist, photoresist), is held in such a way that a radiation-sensitive surface of the substrate is arranged in the region of an image plane of the projection lens, said image plane being optically conjugate with respect to the object plane. During an exposure process, the pattern is illuminated with the aid of the illumination system, which, from the radiation of a primary radiation source, shapes illumination radiation which is directed onto the pattern. The illumination radiation may be characterized by specific illumination parameters and impinges on the pattern within an illumination field of defined shape and size. The radiation altered by the pattern passes as projection radiation through the projection lens, which projects, or images, the pattern onto the substrate to be exposed. The image is generated in the image field of the projection lens.

### SUMMARY

One of the objects in the development of projection exposure apparatuses is to lithographically produce structures having increasingly smaller dimensions on the substrate. Smaller structures lead to higher integration densities, e.g., in semiconductor components, which generally has an advantageous effect on the performance of the micro-structured components produced.

The size of the structures that can be produced is crucially dependent on the resolution capability of the projection lens used. Projection lenses for microlithography generally comprise a plurality of optical elements in order to account for stringent requirements with regard to the correction of imaging aberrations. Refractive and catadioptric imaging systems operating in the DUV (deep ultraviolet) or VUV (vacuum ultraviolet) wavelength range are often used. Those systems typically have ten or more transparent optical elements. In catadioptric systems transparent optical elements are combined with at least one imaging mirror, such as a concave mirror. Electromagnetic radiation from the extreme ultraviolet range (EUV), such as those having operating wavelengths in the range between 5 nm and 30 nm, cannot be focused or guided by refractive optical elements. Mirror systems (catoptric systems) are therefore used for EUV lithography, typically comprising four or six mirrors, for example.

A projection lens necessarily exhibits intrinsic imaging aberrations on account of its optical design and production. On the other hand, transport to and assembly at the customers site as well as environmental changes like, for example, temperature changes and other influences occurring in operation during the service lifetime (such as lens heating), influence aberrations and need to be compensated for.

The type and level of aberrations tolerable for a specific process may vary and are usually given in a set of aberrations specifications which need to be met.

Optical systems, such as a projection lens for a lithography scanner, are specified to an extended image field over which a sufficiently low aberration level needs to be ensured. As every location on an integrated circuit is or can be filled by functional structures, aberrations at arbitrary field points need to be within a common specification.

The imaging aberration level may vary between different field points in the image field. So-called field-dependent aberrations are crucial with regard to, for example, specifications related to overlay. It is mandatory to know and control field-dependent aberrations in order to control the level of overlay errors. The term “Overlay error” refers to, for example, the superimposition accuracy of two successive lithographic planes. Overlay is an important parameter in the fabrication of integrated circuits since alignment errors of any type can cause fabrication faults such as short circuits or missing connections and thus restrict the functioning of the circuit. Inadequate overlay can thus considerably reduce the yield of good parts during fabrication, as a result of which the fabrication costs per good part increase.

Attempts are usually made to at least partly compensate for imaging aberrations that occur during the service life, in particular the imaging aberrations that are generated during operation.

A compensation is often performed by utilizing manipulators integrated into the optical system and/or by exchanging single selected optical elements which can be individually shaped to optimize the system's optical quality.

It is desirable to know the field variation of aberrations with sufficient precision in order to successfully control manipulators or provide an optimal shape of exchangeable elements, and to check the success of these measures.

Many state-of-the-art lithography exposure systems for highest resolutions rely on aberration measurements during production. The results of aberration measurements indicate changes in the optical performance of the projection lens which can be induced, e.g., by thermal effects.

Since the imaging aberration level may vary between different field points in the image field, measuring systems are preferred which are capable of measuring at least one property of the projection radiation relevant for imaging quality or aberration level, respectively, by acquiring measuring data at a plurality of spaced apart measuring points distributed in the image field.

Measuring aberrations at every position (point) in the image field is not practicably possible. For practical reasons, accurate measurements can only be performed at selected spaced apart field points. Potential measurement errors can be limited by, for example, a self-calibration of measurement equipment, wherein multiple measurements are performed at the same field point with different sensors that are fixed in relative positions. In such a situation, the metrology grid is defined by that sensor spacing, thus given by, for example, a grid of similar rectangles. Achieving a finer resolution may be time-consuming and significant additional effort in the measurement equipment would often be required.

A successful correction relies on sufficient information on the field-dependent aberration pattern to be corrected. Generating this information by measurements is expensive, however. A measuring operation should acquire measuring data at a plurality of spaced apart measuring points distributed in the image field.

Each measuring step performed at a measuring point takes time. If a measuring system is capable of measuring at multiple measuring points in parallel, there is typically a limit to the number of field points that can be measured in parallel.

### Object

It is an object of the techniques disclosed herein to provide an economical method of determining field-dependent aberrations in an image field of an optical imaging system, such as a projection lens in a microlithographic projection exposure system. The method may provide fine scale aberration information based on measurements requiring moderate measuring times. It is another object to provide a method capable of performing field dependent aberration measurements with increased metrology robustness while preserving a high system throughput.

A further object is to provide a projection exposure apparatus capable of applying the method and a method of producing a semiconductor device by optical lithography using an optical imaging system set up by the method.

In order to solve these and other problems, the disclosed techniques provide a method comprising the features as claimed and/or described herein. Further, the disclosed techniques provide a projection exposure apparatus comprising the features as claimed and/or described herein and a method of producing a semiconductor device comprising the features as claimed and/or described herein.

Advantageous developments are also specified in the claims and/or descriptions provided herein. The wording of all of the claims is incorporated by reference in the content of the description.

According to one formulation, the disclosed techniques provide a method of determining field-dependent aberrations in an image field of an optical imaging system based on a measuring operation determining aberration data for a plurality of field points in the image field. In this application, the formulation “determining field-dependent aberrations” is used to describe the steps of determining aberration data for a plurality of field points in the image field to quantify how an aberration level varies over the image field. The method comprises multiple method steps.

In one method step, a target grid is defined which comprises a plurality of target field points in the image field. A target field point is a field point for which a level of aberration is to be determined. In general, it would be desirable to have a large number of target field points distributed densely over the image field in order to obtain a close approximation of the actual distribution of aberrations over the image field.

In another method step, a measuring grid is defined comprising a first subset of the target field points comprising all field points for which a level of aberration is to be determined in a measuring operation. In general, the measuring grid includes less field points than the target grid so that measurements are not performed for all target field points.

In a next method step, aberrations are measured at all field points of the measuring grid to generate measured aberration data which represent a wavefront aberration. Once the measured aberration data are available, measured information for all field points of the measuring grid is available; however, no measured aberration data exist for those target field points which do not correspond to the field points of the measuring grid.

In another method step, an auxiliary grid is defined which comprises a second subset of the target field points, wherein the second subset comprises selected target field points not included in the measuring grid for which a level of aberration is to be determined in an aberration data generating operation (ADGO). The aberration data generating operation is configured to generate aberration data for target field points of the auxiliary grid. It is important to note that the aberration data generating operation does not include measurements to determine the aberration level for target field points of the auxiliary grid. Instead, those aberration data are generated based on calculations or simulations which are based on a specific pre-existing knowledge of the optical imaging system and potential system-specific sources (or causes) of aberrations.

In this method, two separate ways of obtaining aberration data are combined. The measuring operation is performed to obtain real measuring data defining the aberration level for the first subset of target field points. A potential aberration level of other field points not belonging to the measuring grid is determined quantitatively in the aberration data generating operation (ADGO), which is not based on measurement. Basically, the method is capable of generating missing data on a fine grid (target grid) by making use of pre-existing knowledge of the optical imaging system and possible causes or sources of aberrations specific to the optical imaging system. In other words: The inventors propose a hybrid approach combining measured data and data consistent with the measured data, but obtained based on calculations which are performed based on certain pre-existing knowledge about the optical imaging system.

By using the method, measurement errors of optical aberrations are typically reduced in comparison to other metrology schemes of comparable effort. The method in combination with actuation devices, in particular rigid body manipulators for reticles (i.e., masks), optical elements and substrates (e.g., wafers), but also with adaptive elements, such as a rapid fine scale full field aberration measurement, enables a superior correction strategy to reduce optical aberrations, which allows conformity with increasingly tight specifications in future systems without a need to compromise in production speed.

In preferred embodiments, the aberration data generating operation comprises a reconstructing step and a forward calculation step. The reconstructing step includes reconstructing at least one (virtual) perturbation of at least one optical element of the optical imaging system consistent with an aberration fingerprint determined based on the measured aberration data in the measuring grid. In the forward calculation step, a forward calculation is executed based on the perturbations obtained in the reconstructing step to determine field aberration data for all field points in the target field.

In this context, the term “perturbation” describes a condition deviating from a reference condition. For example, an optical surface of a mirror or a lens in an optical imaging system has a nominal shape (surface figure) corresponding to the shape defined in the optical specification.

In reality, the surface shape will differ from its nominal shape due to manufacturing tolerances and other influences. The difference, i.e., the deviation of the shape of a real optical surface from a nominal shape of the optical surface according to the specification, is denoted as the “surface figure error” (described by the term “Passe” in the German language). The surface figure error may be the only contribution to a “perturbation.” However, an optical surface may have a perfect shape, but the optical element as a whole may be mounted in a way slightly deviating from specification, thereby introducing deviations of pose (position), e.g., tilt, decentering, etc. Also, mounting stresses may occur, contributing to a perturbation. In general, a perturbation may be decomposed into several components, such as a tilt component, a decentering component and components describing deformations.

More specifically, the term “perturbation” is a generic term describing deviations from the ideal situation according to the optical design. A perturbation may include rigid body position errors of optical elements, such as decentering, rotation or tilting. Alternatively, or in addition, surface figure errors contribute to perturbations. Those errors may have a disturbing effect only locally or at higher spatial frequencies. In general, it is often difficult or impossible to strictly separate perturbations originating from rigid body movements from perturbations originating from surface figure errors. For example, if an optical surface is dislocated to a small extent, the effect may resemble the effect of a surface deformation transforming the original surface figure to the surface figure on the dislocated position. Therefore, a perturbation may be described in terms of decentering as well as in terms of a surface figure error having an identical influence on the aberrations.

The method may be performed in such a manner that measured aberration data are assumed to be “true” so that the measured data may serve as fixed values. In another approach, the measured values may be varied in the course of the method of finding a best fitting aberration pattern. In many cases, measured aberrations of higher order may be assumed to be true values, while aberrations with lower orders, which are typically associated with a higher degree of uncertainty (such as tilt or defocus), may be measured multiple times to obtain effective values by obtaining average values and/or an adaption based on multiple measurements to obtain a best possible approximation of the true aberration values. The method may be performed so that each aberration is measured only once. However, it is also possible to perform multiple measurements (two or more) for some or all aberrations. In the case of multiple measurements, multiple measurements are typically accompanied by subsequent data processing to determine average values or adaptations.

An important aspect of the new approach described in this application may be described so that the method allows deriving from the measurement a potential origin or source of errors which is compatible with the optical elements present in the concrete, real system. For example, if the optical system consists of mirrors only, with a vacuum between the mirrors, it is highly likely that aberrations originate from defects or errors on the mirror surfaces rather than on conditions in the intermediate spaces between the mirror surfaces. The method considers specific limitations of the concrete system under inspection to reduce the number of possible causes of errors.

The reconstructing step includes backward calculations to find out a relation between certain kinds of virtual perturbations and their influence on the aberration distribution in the image field.

The term “aberration fingerprint” describes the specific pattern of field-dependent aberrations which has been determined in the measurement steps. It is important to note that the reconstructing step does not provide (positive) proof that a certain perturbation assumed to be responsible for a certain aberration in the image field is the real cause of the aberration. Instead, the reconstructing step is configured to find certain properties of perturbations which are consistent with the measuring data. In other words: The measuring data could be explained by assuming that the virtual perturbations assumed in the reconstructing step are actually those perturbations which exist in the optical imaging system. The actual perturbations existing in the measured system may deviate from those virtual perturbations found by the reconstructing step to be consistent with the measured aberration fingerprint.

As explained above, the method partly relies on pre-existing knowledge of certain properties of the optical imaging system. This reduces significantly the number of degrees of freedom existing in modelling how a certain aberration fingerprint determined by the measuring step could be explained in terms of actual structure of the optical imaging system. In a preferred embodiment, the knowledge of the optical system comprises design data describing or representing a specification of a nominal optical design of the optical imaging system. The design data comprise surface figure data describing for each optical surface of the optical imaging system, a nominal surface figure according to the specification. The surface figure data may include coefficients describing a base curvature (or radius of curvature) of an optical surface, coefficients describing potential deviations from a spherical shape, distance data describing a distance between the optical surface and neighboring optical surfaces, the size data describing the size of the portion of the optical surface actually used when the optical system is used (sometimes denoted “optical free diameter”) etc. More complex data may be required to describe the shape of freeform surfaces, which may deviate significantly from any rotational symmetric spherical or aspherical surface shape. The design data further include index data indicating the optical nature of the optical surface to distinguish between reflective surfaces (e.g., mirror surfaces) and refractive surfaces.

The design data describe the “ideal” optical system developed by an optical designer to achieve certain performance specifications. Generally, this ideal configuration is not entirely achieved in the real optical system due to manufacturing tolerances, environmental conditions, etc. Despite those deviations, the design data provide crucial information about what kind of deviations from the ideal case (perturbations) would typically be more likely than others, thereby reducing the degrees of freedom in the analytic steps.

In preferred embodiments, the knowledge of the optical system comprises perturbation data, wherein the perturbation data comprise sensitivity data. The sensitivity data describe, for each optical surface of the optical imaging system, a relation between a surface figure error and a contribution to a wavefront aberration caused by the surface figure error. The surface figure error (described by the term “Passe” in the German language) describes the deviation of the shape of a real optical surface from a nominal shape of the optical surface according to the specification. The sensitivity data basically describe the system behavior of the optical system in terms of the influence of surface figure errors on the wave front of radiation having passed the optical system towards the image field.

In preferred embodiments, the reconstructing step includes setting a refractive index of interspaces between the optical surfaces to the value 1. This limitation strongly reduces the possible patterns of aberration variations and allows finding reasonably correct aberration at non-measured positions even with reduced metrology information. This assumption makes use of the fact that, in the case of a vacuum existing between the optical elements, as is typical in EUV applications, it is clear that aberrations will necessarily be generated by the optical elements or the surfaces themselves and nowhere else. This fact strongly reduces the number of potential sources of perturbations, thereby making the model less complex and calculations more efficient.

However, the method is not restricted to determining field-dependent aberrations in optical imaging systems for EUV. Instead, the method can also be used to obtain the required information for systems working in, for example, the deep ultraviolet range (DUV) where the interspaces between lenses and/or mirrors may be filled with gas instead of vacuum. It has been found that the method still yields reasonably precise results when the possible influence of the interspaces on the wave front aberrations is neglected.

There are still other considerations which help to reduce the possible numbers of degrees of freedom in the reconstructing step. In preferred embodiments, a mesh width of the measuring grid is set such that distances between target field points of the first subset are small enough such that sub-apertures associated with the target field points overlap and encompass an entire useful area on each of the optical surfaces of the optical imaging system (or at least 80% or at least 90% or at least 99% thereof). Obeying this condition makes sure that any perturbation on each of the optical surfaces will have an influence of the measured result because the measuring grid is fine enough so that no gaps or blind spots exist on any of the optical surfaces. In other words: If this condition is not obeyed, there is a risk that a perturbation actually existing on one of the surfaces does not show in the measuring data so that the measuring data do not represent entirely the perturbation patterns on each of the surfaces.

This formulation makes use of the term “sub-aperture”, which can be explained as follows. In an optical imaging system, a beam emerging from a specific field point in the object field or converging towards a certain image field point in the image field has a certain aperture.

Therefore, the beam intersects an optical surface disposed at a distance from the field plane in a certain intersection area, which may be, for example, circular or elliptical in shape and is denoted as “sub-aperture” in this application. In the case of a divergent beam the sub-aperture diameter increases with increasing distance from the field. All sub-apertures overlap in a pupil surface having a Fourier transform relationship to a field plane. On the other hand, sub-apertures may not overlap at all if an optical surface is optically close to the next field plane. In terms of mesh size of the measuring grid, this means that the measuring grid may have to be designed finer if the optical system includes one or more optical surfaces close to a field plane.

The disclosed techniques also relate to a projection exposure apparatus capable of applying the method and a method of producing a semiconductor device.

### BRIEF DESCRIPTION OF THE DRAWINGS

These and further features emerge not only from the claims but also from the description and the drawings, wherein the individual features can be realized in each case by themselves or as a plurality in the form of sub-combinations in an embodiment of the disclosed techniques and in other fields.

Exemplary embodiments are illustrated in the drawings and are explained in greater detail below.

FIG. 1 shows components of an EUV microlithography projection exposure apparatus;

FIG. 2 shows a comparison between contributions to wavefront aberration components Z2-Z5 of an example of an aberration simulating a measurement on a coarse grid and a fine grid;

FIG. 3A shows examples of coarse measuring grids in an arcuate image field;

FIG. 3B shows examples of fine measuring grids in an arcuate image field;

FIG. 4 shows an exemplary process flow from coarse grid metrology to fine field aberration fingerprint;

FIG. 5 shows a reconstruction result of a surface figure deformation;

FIG. 6 shows respective aberrations related to the surface figure deformations shown in FIG. 5.

### DETAILED DESCRIPTION

In the following, concepts and aspects of the disclosed techniques and embodiments thereof disclosed in this application will be described using a EUV microlithography projection exposure system as an example. A skilled person recognizes that the examples are not limiting to such a system. For example, the concepts may also be used in connection with systems working in other wavelength ranges, such as DUV (deep ultraviolet) systems.

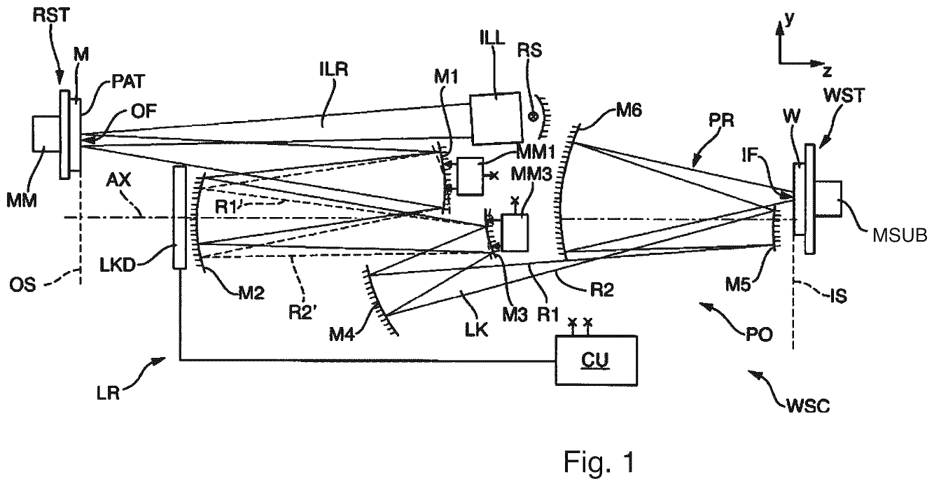

FIG. 1 schematically shows components of an EUV microlithography projection exposure apparatus WSC for exposing a radiation-sensitive substrate W arranged in the region of an image plane IS of a projection lens PO with at least one image of a pattern PAT of a reflective mask M, said pattern being arranged in the region of an object plane OS of the projection lens.

The projection exposure apparatus is operated with the radiation of a primary radiation source RS. An illumination system ILL receives the radiation of the primary radiation source and shapes illumination radiation ILR directed onto the pattern. The projection lens PO is an optical imaging system configured to image the structure of the pattern onto the light-sensitive substrate W.

The primary radiation source RS can be, inter alia, a laser plasma source, a gas discharge source, or a synchrotron-based radiation source. Such radiation sources generate a radiation in the extreme ultraviolet range (EUV range), in particular, radiation having wavelengths of between 5 nm and 15 nm. In order that the illumination system and the projection lens can operate in said wavelength range, they are constructed with components that are reflective to EUV radiation.

The radiation emerging from the radiation source RS is collected by a collector and directed into the illumination system ILL. The illumination system shapes the radiation and, with the shaped illumination radiation ILR, illuminates an illumination field lying in the object plane OS of the projection lens PO or in proximity thereto. In this case, the form and size of the illumination field determine the form and size of the effectively used object field OF in the object plane OS. The illumination field is generally in the shape of a slot having a high aspect ratio between width (in x-direction) and height (in y-direction).

The projection lens PO here has six mirrors M1 to M6 and images the pattern of the mask, on a reducing scale, into the image plane, in which the substrate to be exposed, e.g., a semiconductor wafer, is arranged. The image field IF, which is optically conjugate with respect to the object field, lies in the image plane. All of the mirrors are coated with multilayer reflection coatings which have a reflective effect for EUV radiation and which can contain, for example, Mo/Si layer pairs (bilayer).

The projection radiation PR passing from the mask M to the substrate is successively reflected at the six mirrors (first mirror M1 to sixth mirror M6). All rays which pass from the object field to the image field and which contribute to image generation form the projection beam path.

A device RST for holding and manipulating the mask M (reticle) is arranged such that the pattern PAT arranged on the mask lies in the object plane OS of the projection lens PO, which is also designated here as the reticle plane. The mask is movable in this plane for scanner operation in a scanning direction (y-direction) perpendicularly to the reference axis AX of the projection lens (z-direction) with the aid of a scan drive.

The substrate W to be exposed is held by a device WST comprising a scanner drive in order to move the substrate synchronously with the mask M perpendicularly to the reference axis AX in a scanning direction (y-direction). Depending on the design of the projection lens PO, these movements of mask and substrate can be effected in a manner parallel or antiparallel with respect to one another.

The unit WST, which is also designated as “wafer stage”, and the unit RST, which is also designated as “reticle stage”, are part of a scanner unit controlled by a scanning control unit, which in the case of the embodiment is integrated into the central control unit CU of the projection exposure system. A data storage (not shown) is associated with the control unit.

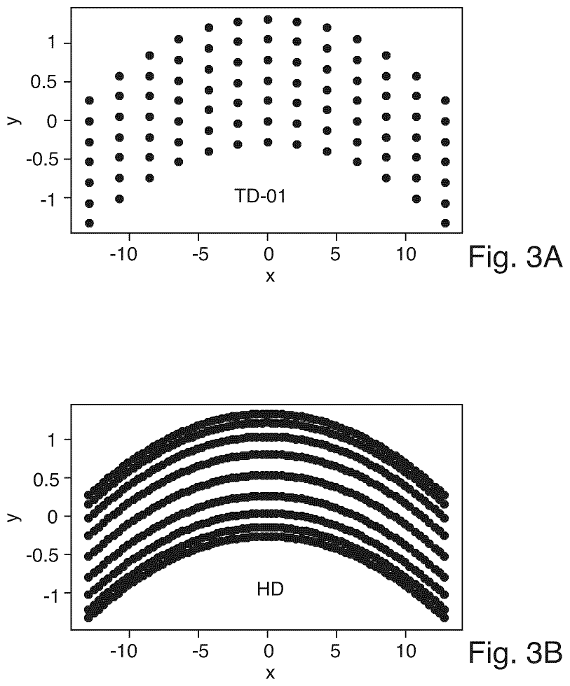

The object field OF and the corresponding image field IF have an arcuate shape in the embodiment (compare FIGS. 3A and 3B). The size of the image field IF is smaller than the size of the object field and related to the size of the object field OF by the reduction ratio provided by the projection lens.

All optical components of the projection exposure system WSC are accommodated in a housing which can be evacuated. EUV projection exposure systems having a similar basic construction are known from, for example, WO 2009/100856 A1 WO 2010/049020 A1 or WO 2015/049319 A1 the disclosure of which are hereby incorporated by reference in their entirety.

Other embodiments may have different layouts. For example, the projection lens may have more than six mirrors, e.g., eight mirrors, ten mirrors, or more. The reduction ratio need not be isotropic (i.e., the same in all direction in the field). Instead, the projection lens may have an anamorphotic design resulting in reduction ratios which differ between the scan direction and the cross scan direction.

The projection exposure apparatus WSC has an operating control system configured for performing a near-instantaneous fine optimization of imaging-relevant properties of the projection exposure apparatus in reaction to environmental influences and other disturbances and/or on the basis of stored control data. For this purpose, the operating control system has a multiplicity of manipulators that allow a targeted intervention in the projection behavior of the apparatus. An actively drivable manipulator contains one or a plurality of actuating elements or actuators, the present actuating value of which can be changed on account of control signals of the operating control system by defined actuating value alterations being performed.

A mask manipulator MM has actuators which, depending on driving, can bring about a displacement of the mask M parallel to the reference axis AX or perpendicular thereto and a tilting of the mask as a whole. The mask manipulator can also be designed such that, alternatively or additionally, a deformation of the mask can be performed.

A substrate manipulator MSUB has actuators which make it possible to alter the position of the substrate with respect to the projection lens by displacement parallel to a reference axis or displacement perpendicular thereto and/or by tilting and/or to deform the substrate.

The first mirror M1, which directly follows the mask or the object plane in the radiation transmission direction, can be tilted and/or displaced transversely with respect to the light propagation direction and/or deformed by a first mirror manipulator MM1.

Corresponding mirror manipulators can also be provided for one or more of the other mirrors. In particular, in the present case, a third mirror manipulator MM3 is provided at the third mirror M3, which third mirror manipulator can displace and/or tilt and/or deform the third mirror as a whole transversely or parallel to the light propagation direction.

Control of manipulators may be performed based on measurements.

The projection exposure system is equipped with a measuring system MES, which, in the embodiment, is designed to perform a measurement of the wavefront of the projection radiation which passes in the projection lens from the mask to the substrate to be exposed. A spatially resolving measurement for a plurality of field points on image surface level is possible. By way of example, it is possible to provide wavefront measuring systems of the type described in U.S. Pat. No. 7,333,216 A1 or U.S. Pat. No. 6,650,399 A1, the disclosures of which are incorporated herein by reference in their entirety.

The measuring system may include an integrated lens interferometers at scanner (ILIAS). An ILIAS is an interferometric wavefront measurement system that may perform static measurements on lens aberrations up to high order. It may be implemented as an integrated measurement system used for system initialization and calibration. Alternatively, it may be used for monitoring and recalibration “on-demand”.

All optical components of the projection exposure apparatus WSC are accommodated in an housing which can be evacuated. The projection exposure apparatus is operated under vacuum.

EUV projection exposure apparatuses having a similar basic construction are known from, for example, WO 2009/100856 A1. Projection lenses having a similar basic construction are known from, for example, U.S. Pat. No. 6,927,901 B2. The disclosures of which are incorporated herein by reference in their entirety.

Since the imaging aberration level may vary between different field points in the image field, the measuring system is configured such that it is capable of measuring at least one property of the projection radiation relevant for imaging quality or aberration level, respectively, by acquiring measuring data at a plurality of spaced apart measuring points distributed in the image field.

In order to quantitatively characterize the spatial variation of the aberration level across the field in a specific situation, a “target grid” may be defined. The target grid comprises a plurality of target field points in the image field, wherein a target field point is a field point for which a level of aberration is to be determined. Further, a measuring grid may be defined, the measuring grid comprising a first subset of the target field points comprising all field points for which a level of aberration is to be determined in a measuring operation. Further, an auxiliary grid may be defined, the auxiliary grid comprising a second subset of the target field points comprising selected target field points not included in the measuring grid for which a level of aberration is to be determined without measuring at these points. In the embodiment, an aberration data generating operation is utilized to generate aberration information for the field points of the auxiliary grid.

The field points which can be measured are distributed across the image field according to a two-dimensional measuring grid characterized by a certain mesh width. Spatial resolution of the measurement in a selected direction scales with the mesh width in the respective direction. The smaller the mesh width (i.e., the distance between adjacent measuring field points), the finer is the spatial resolution. FIGS. 3A and 3B show examples of measuring grids in an arcuate image field. The coarse grid (reference identifier TD01) in FIG. 3A) includes 13*7=91 measuring points, whereas the fine grid (reference identifier HD in FIG. 3B) includes 73*9=657 measuring points.

The inventors of the disclosed techniques developed ways to obtain aberration data describing a variation of imaging aberrations over the image field on a fine spatial scale without needing to measure each aberration component at all field points corresponding to the fine scale. This approach is partly based on the understanding that some imaging aberration components are easier to measure than others. Some basic concepts are now described using an aberration description on the basis of Zernike wavefront functions.

In the field of geometrical optics, Zernike polynomials are usually used to represent wavefronts that in turn describe the imaging aberrations of optical systems. In this context, the individual imaging aberrations can be described by the coefficients of the Zernike polynomials, that is to say the Zernike coefficients or the values thereof (in [nm]). In the representation chosen here, the Zernike coefficients Z2 and Z3 represent the tilting of a wavefront in the x-direction and y-direction, respectively, as a result of which a distortion-like aberration arises. The Zernike coefficient Z4 describes a curvature of the wavefront, whereby a defocus error can be described. The Zernike coefficient Z5 describes a saddle-shaped deformation of the wavefront and thus the astigmatism component of a wavefront deformation. The Zernike coefficients Z7 and Z8 represent coma, the Zernike coefficient Z9 represents spherical aberration, and the Zernike coefficients Z10 and Z11 represent three leaf clover.

The concept also uses system sensitivities to describe the system behavior as a whole. In the context of this application, a sensitivity describes a functional relationship between a specific perturbation component and its effect on the wavefront. To give an illustrative example, consider a mirror within an optical system. Tilting the mirror normally moves the image position, which accordingly is very sensitive to such a tilt. A system astigmatism, in contrast, also “feels” the tilt, but with a significantly lower sensitivity. A certain perturbation (here: tilting a mirror) is therefore connected to a certain set of aberration component with different sensitivities.

Using an aberration description on the basis of Zernike wave front functions, it turns out that some aberrations having higher spatial frequencies across the field cannot be measured with sufficient reliability by measurements at measuring points distributed on a coarse grid (i.e., a grid of measuring points distributed over the field according to a grid characterized by a relatively lower spatial frequency). Instead, some kind of undersampling may occur if there is an unfavorable misfit between the spatial frequencies of the aberration and the respective measuring grid.

In other words: where high-frequent features (i.e., features having high spatial frequency over the field) cannot be resolved on a coarse grid with sufficient accuracy, relevant information would be missing if the single source of information is a measurement of aberrations on the coarse grid.

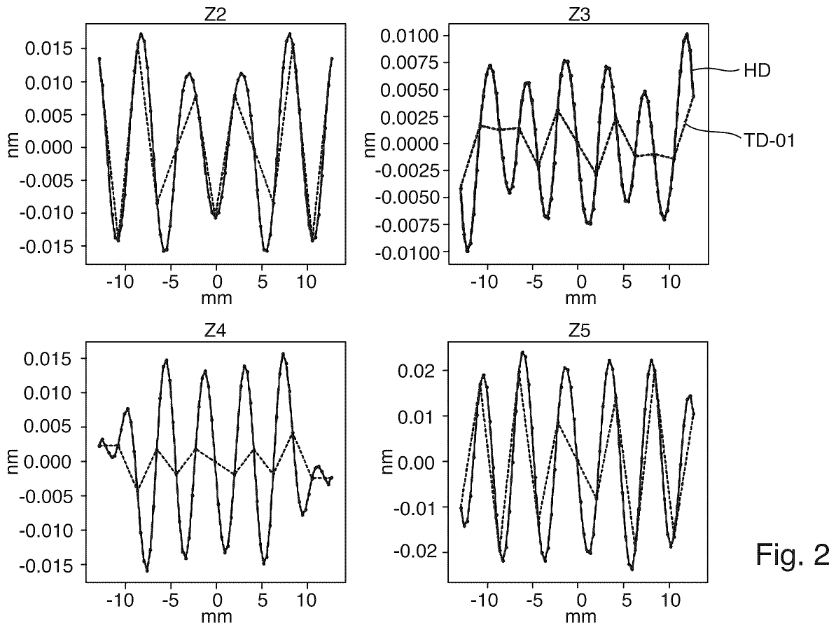

To further illustrate this problem, FIG. 2 depicts the Z2-Z5 contribution to wavefront aberration of an example of an aberration simulating a measurement on a coarse grid TD-01. A comparison of the same aberration given on the fine grid HD shows the incompleteness. Each diagram shows the field coordinate in the x-axis (field center at x=0 nm) and the amplitude of the wavefront aberration of the respective Zernike coefficient on the y-axis.

Each diagram shows the exemplified aberration (Z2-Z5 contributions) on a coarse grid (TD01-grid) and a fine grid (HD-grid). As shown in FIG. 3, the coarse grid (FIG. 3A) includes 13*7=91 measuring points, whereas the fine grid (FIG. 3B) includes 73*9=657 measuring points.

A mesh width of measuring points of the finer grid (HD-grid) is selected small enough so that the sub-apertures assigned to the field points on the HD-grid cover the entire surface of all optical elements being relevant for the image creation process. In contrast, the sub-apertures of the coarse grid leave clearances on some optical elements. In other words: measurements on the coarser grid may be “blind” to deformations in those regions outside the covered sub-apertures, whereby important information may not be accessible.

Whereas the overall shape with respect to the spatial frequency, number and height of peaks of Z2 and Z5 is reasonably similar, a significant undersampling is observed in case of Z3 and Z4. This indicates that a measurement of these aberrations on a coarse grid would lead to a loss of information.

In practical examples it turns out to be difficult to achieve a fine spatial resolution for Zernike Z2-Z4, whereas Zernikes between Z5 and Z100 can be measured on a fine grid with moderate effort in time and equipment complexity. The inventors believe that the reason for this observation may be described as follows. Some sources of errors which may have strong influence on Z2 to Z4 in an isomorphotic system or on Z2 to Z5 in an anamorphotic system appear to occur in a more diverse way and more often than other sources of error, which predominantly influence other aberrations, such as Z5 or Z6. In the context of this application, Z2 describes a tilt of the wavefront in x direction, Z3 corresponds to a wavefront tilt in y direction (scanning direction) and contributions to Z4 are easily generated by dislocating an optical element in the direction of the propagation of radiation. In an anamorphotic system a dislocation of the mask (reticle) with a component perpendicular to the object surface may generate a strong influence on Z5 due to the difference between lateral and longitudinal imaging scale. Further, it appears that some metrology systems which include movable sensors to generate measurements on different field points may have a stronger influence on the measurement accuracy of Z2 up to Z4 or Z5 when compared to higher order Zernikes. In view of these observations it appears appropriate to differentiate between aberrations with lower order (e.g., Zernike Z2 to Zernike Z4, for example) on the one hand and higher order Zernikes (e.g., between Z5 and Z100) on the other hand.

The inventors of the disclosed techniques developed a way to obtain reasonably fine scale information about Z2-Z5 from measurement of these Zernike coefficients on a coarse scale supplemented by information derived from a measurement of the better resolved high-order Zernike coefficients.

It is thereby possible to find an aberration picture on a fine grid based on measurements of at least some aberrations on a coarser grid. The method includes generating missing data on the fine grid by making use of knowledge of the optical system and the possible system specific origins (root causes) of aberrations.

In the following an embodiment will be described using a projection lens for EUV lithography as an example. The exemplary model projection lens has six mirrors M1 to M6 contained in an evacuated housing. For vacuum (refractive index=1) between the optical elements, it is clear that aberrations are generated by the optical elements themselves (i.e., by the mirrors) and nowhere else. This fact reduces the number of possible patterns of aberration variation and facilitates finding the correct aberrations at non-measured positions even with reduced metrology information.

The method includes an aberration data generating operation (ADGO) configured to generate aberration data for target field points of an auxiliary grid based on (i) knowledge of the optical imaging system and (ii) potential system-specific causes (root sources) of aberrations.

The auxiliary grid is a grid comprising a second subset of the target field points comprising selected target field points not included in the measuring grid for which a level of aberration is to be determined.

The aberration data generating operation includes a reconstruction step to reconstruct at least one (virtual) perturbation of at least one optical element of the optical imaging system consistent with an aberration fingerprint determined based on the measured aberration data in the measuring grid, and a forward calculation based on the perturbations obtained in the reconstructing step to determine field aberration data for all field points in the target field.

In the embodiment, the reconstructing step includes setting a refractive index of interspaces between the optical surfaces of the mirrors to the value 1, thereby reducing significantly the complexity of the model.

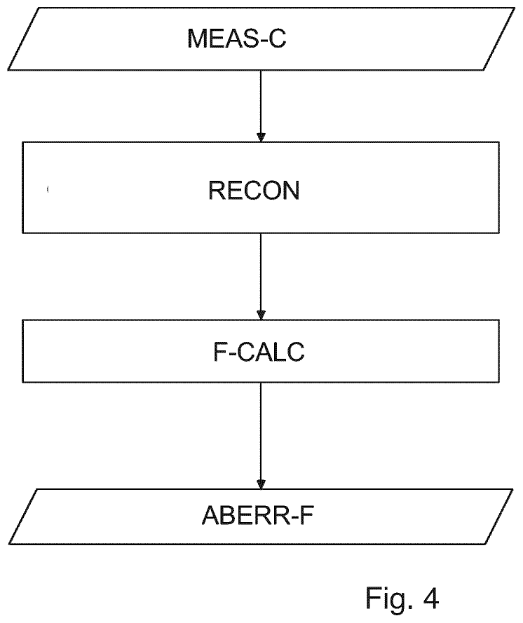

The procedure is illustrated schematically in FIG. 4 illustrating an exemplary process flow from coarse grid metrology to fine field aberration fingerprint.

In general, measured aberrations are traced back to perturbations of the optical elements. In this case the perturbations are mirror surface deformations representing the fact that an actual surface figure or surface shape of a reflective mirror surface deviates from its nominal shape defined in the specification of the optical system.

In the measuring step, MEAS-C, aberrations are measured on a coarse grid. The results of the measurements yield an “aberration fingerprint”, i.e., a pattern of aberrations characteristic for the measured system. Step RECON represents the reconstruction of perturbations of optical elements generating the observed aberration fingerprint. This step yields a set of deformations consistent with the measured aberrations. In this context, the term “consistent” means that the deformations determined in the RECON step conform to the character of the measurement results (to the aberration fingerprint) without contradiction. The reconstruction step does not necessarily yield the real deformations, however the deformation pattern found in the reconstruction step is more likely than other deformation patterns which could be responsible for the measured aberration fingerprint.

In the next step F-CALC a forward calculation is performed calculating aberration patterns on a fine grid based on the deformations obtained by the reconstruction step. The forward calculation calculates an aberration pattern which would result if the mirrors of the optical system under inspection would actually suffer from the deformations found in the reconstruction step. The forward calculation step is expected to yield the correct (measured) aberrations on the field points observed in the measurements and, in addition, consistent aberrations for field points which have not been measured, i.e., aberrations on field points of the finer grid (ABERR-F).

Adding information from higher Zernike wave front coefficients on a finer grid fills possible gaps as a consistent combination of perturbations, say surface deformations, compatible with these higher Zernikes will be reconstructed. This reconstruction only turns out to be unique if a sufficient amount of high order information is included.

Technically the reconstruction may be performed by tomographic algorithms known in the state of the art, such as distributed back propagation in which, for example, missing low order Zernike information is simply left out in this process. Alternatively, or in combination, reconstruction may be executed by least square fits of sensitivities of optical element perturbations to the measured data. So, for a pre-defined degree of freedom set of mirror surface deformations, which can be Zernike-adapted to the mirror shape, spline functions or other function bases known in the state of the art, the influence on the wave front characteristics measured can be calculated by optical simulation. Additional high-order Zernike information on a fine grid can be obtained in the same way.

In an embodiment, the procedure to reproduce the underlying deformations from the aberrations is carried out using a Tikhonov-type algorithm. As already mentioned, the set of base functions to describe the occurring aberrations consists of mirror-shape-adapted Zernikes composing the manipulator matrix MM, where Z2-Z5 are resolved on the coarse TD01-grid and the higher-order Zernikes are given on the fine HD-grid. Exemplary details are given below.

The merit function of the optimization is: Mx+p=0, where M is the manipulator matrix, x is the target vector and p is the perturbation. This equation can be formally solved for x so as to obtain: x_{rec}=−M⁻¹p. The individual parts of the equation have the following meaning:

### Perturbation p:

The wavefront of the perturbation is decomposed into wavefront Zernike coefficients:

Example of a coarse field grid, called A, consisting of only one field point:

$$WFR at {FP}_{A} = {a}_{Z 2} ( F {P}_{A} ) \cdot Z 2 + {a}_{Z 3} ( F {P}_{A} ) \cdot Z 3 + {a}_{Z 4} ( F {P}_{A} ) \cdot Z 4 + …$$

Example of a fine field grid, called B; consisting of two field points:

$$WFR at {FP}_{B 1} = {a}_{Z 2} ( F {P}_{B 1} ) \cdot Z 2 + {a}_{Z 3} ( F {P}_{B 1} ) \cdot Z 3 + {a}_{Z 4} ( F {P}_{B 1} ) \cdot Z 4 + …$$

$$WFR at {FP}_{B 2} = {a}_{Z 2} ( F {P}_{B 2} ) \cdot Z 2 + {a}_{Z 3} ( F {P}_{B 2} ) \cdot Z 3 + {a}_{Z 4} ( F {P}_{B 2} ) \cdot Z 4 + …$$

where a_{Z2}(FP_{A}) is the evolution coefficient for Z2 at field point A.

In the perturbation vector pᵢ the wavefront Zernike coefficients a_{Zi} for all Zernikes and all field points are arranged one below the other and thus describe the wavefront effect of the perturbation.

### Manipulator Matrix M:

The manipulator matrix Mᵢⱼ comprises the set of all basic functions. The basic functions correspond to sensitivities, which may also be described as Zernike coefficients adapted to the mirror shape. Here, the sensitivities are expressed similarly to the perturbation by wavefront Zernike coefficients. A single sensitivity, for example a tilt of 1 μm in x-direction of a mirror, leads to a certain wavefront effect at the output of the lens (i.e., in the image field). Therefore, similar to the perturbation, the index i refers to the wavefront Zernike coefficients at all field points. The index j refers to the sensitivities (describing surface deformations) and runs over all optically active surfaces of the lens and all possible surface deformations, e.g., tilt.

Similar to the perturbation, the manipulator matrix M comprises both the wavefront Zernike coefficients of the few measurement points of the coarse grid (measuring grid, e.g., for Z2-Z5) and the coefficients of the many measurement points of the fine grid (e.g., for >Z5).

### Target Vector x

The target vector xⱼ comprises the coefficients of the surface sensitivities (Zernike coefficients adapted to mirror shape). The product of manipulator matrix M and target vector x represents the wavefront effect of the target vector.

The above equation Mx+p=0 is injective in the case that M has more rows than columns. In this case, there is a unique solution x and the wavefront is exactly reproduced. On the other hand, if M is not injective, there is a null space with Mx′=0 und M (x+x′)+p=0. If this equation is to be solved for x, there is no unique solution and thus other solutions would be possible. For this reason, the sensitivities must be built up accordingly so that there is enough information to find a unique solution.

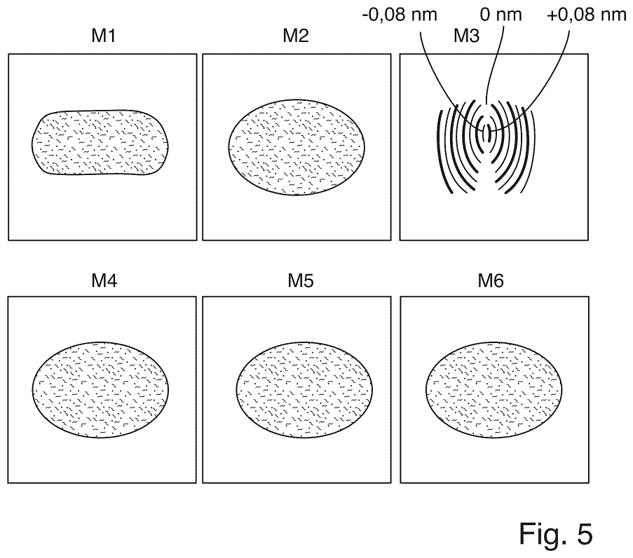

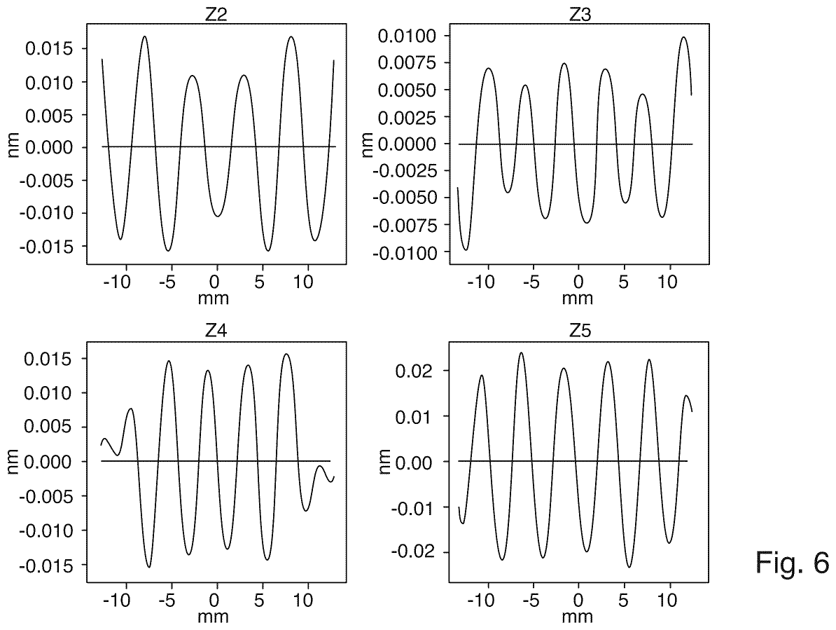

FIG. 5 and FIG. 6 show the reconstruction result of a surface figure deformation (FIG. 5) and the respective aberration, which reproduces the input precisely (FIG. 6). The model optical system consists of six mirrors M1 to M6. Only the third mirror M3 exhibits surface deformations so that the shape of the reflective surface of M3 deviates from specification. FIG. 5 shows that the reconstructed surface figure deformation is perfectly reproduced by the algorithm. FIG. 6 shows that the aberration reconstructed from the surface figure deformation (FIG. 5) agrees perfectly with the input data. Line DIF represents the difference between input data and reconstruction. The additional information can only stem from higher-order Zernikes. This method is thus proved to work for this specific case.

Inventors found that the spatial frequency of a perturbation plays an important role when it comes to a reconstruction to identify which optical element is predominantly responsible for the perturbation. In general, it is often difficult to draw exact conclusions from the result (aberration) to the cause (error on an optical element, for example). In the simulations explained in connection with FIGS. 5 and 6 a relatively simple perturbation was assumed which was expected to be reconstructable with sufficient preciseness by an appropriate algorithm. The mirror M3 chosen as the example is a mirror capable of influencing the wavefront in a field dependent manner due to the specific position in the radiation path. This specific position facilitates a reconstruction with high precision. In this context inventors observed that the spatial frequency of perturbation may play an important role when it comes to identifying the most likely source of an aberration. The higher the spatial frequency is, the easier it is to associate measured errors with a specific originator. In the present case a perturbation with high spatial frequency was assumed, which facilitates identifying the correct originator of the aberrations.

Care needs to be taken in choosing an appropriate ratio of wave front Zernikes and basis function (mirror-shape adapted) Zernikes. As already mentioned, a unique reproduction obtained from this very procedure can only be guaranteed for an injective manipulator matrix under the necessary prerequisite of having more rows than columns. In this case zero modes which could not be resolved and lead to ambiguity in reconstruction can be excluded. In other words, use sufficient information to resolve between all degrees of freedom you are interested in.

As already mentioned, the perturbation p can only be represented appropriately if it somehow matches the choice of base functions or the number of base functions is sufficiently high. However, the introduction of weight factors and regularization factors can improve the result of the reproduction.

What set of degrees of freedom is used needs to be adapted to real world effects. Simulations on stress effects as well as measured figure data typically give examples the perturbation functions are fitted to. If, for example, mirror surface deformations are considered, for a given set of measured and/or simulated deformation states a function base is to be defined, which, in the beginning, may have variable size and calculate for every sample state the residual, which remains after fit depending on the number of degrees of freedom. The minimum number that in all cases brings that residual below an acceptable level would be a good choice. However, increasing this number gives some margin for unforeseen contributions, increases the complexity and the amount of measurement information required.

The choice of the fine grid can be motivated by the requirement to ensure an acceptable level of perturbations on every optical element after correction by gaining sufficient knowledge on that perturbation. The joint area of sub-apertures of all field points of the fine grid ideally fully cover every optical element. Neighboring sub-apertures often overlap, which provides redundancy leading to a lower sensitivity on measuring errors that average out depending on the number of sub-apertures covering a given position on an optical element. FIG. 3 depicts two grids with different spatial resolutions which were used to simulate the measurement.

If one controls all optical elements in this way, it is ensured automatically that even at positions not covered by the fine grid no surprises appear. Sometimes it is acceptable to reduce the 100% requirement to, say, 90%, if, e.g., by the production process it is ensured that the unknown regions are of comparable quality to the regions influencing the measurement as well. Depending on the correction degrees of freedom considered, a reduced information on perturbations can be also sufficient. If, e.g., rigid body degrees of freedom only are available for correction, but no change of individual surface figures is planned, comparably few aberration patterns can be compensated for at all. In these situations, a very detailed knowledge on surface figures, which are not accessible to the correction recipe, is of little use and does not lead to any improvement.

Some aspects of the present disclosure may be formulated as follows:

The disclosure relates to method of providing performance information on a fine field grid for an optical system. The method is characterized by measuring at least part of that performance information on a coarser grid, reconstructing root cause perturbations in the optical system compatible with the measured performance data and generating performance data on the fine grid based on these reconstructed perturbations. An indirect information transfer between different aberrations is thus established.

In a preferred embodiment, the number of performance characteristics measured, which is used for reconstruction, equals or exceeds the overall number of reconstruction degrees of freedom. In a further preferred embodiment, the measurement positions are given by the edge points on a grid of equally sized rectangles.

One aspect may be described as a method where the optical system is an EUV lithography projection optics and the root cause perturbations are mirror surface deformations which may be generated by mounting stress, surface figure errors from the production process or resulting from material degradation over lifetime like compaction.

A method is disclosed which can improve the optical performance of an optical system by first applying the method to generate aberration information on a fine grid, secondly generating and performing a compensation recipe which may use manipulators present in the optical system and/or at least one exchangeable optical element which can individually be shaped to optimally influence the field dependent aberration pattern on the fine grid.

Preferably, the sub-apertures of the fine grid cover at least 80%, preferably 90%, further preferably 99% of each optical element. That way it is ensured that field positions outside the fine grid also exhibit a sufficiently low aberration level.

The disclosure also relates to a method of producing a semiconductor device by optical lithography using an optical system set up using the method of determining field-dependent aberrations.

What is claimed is:

1. A method of determining field-dependent aberrations in an image field of an optical imaging system based on a measuring operation determining aberration data for a plurality of field points in the image field, the method comprising:
defining a target grid comprising a plurality of target field points in the image field, wherein each target field point of the plurality of field points is a field point for which a level of aberration is to be determined;
defining a measuring grid comprising a first subset of target field points of the plurality of target field points comprising all field points for which a level of aberration is to be determined in a measuring operation;
performing the measuring operation, the measuring operation comprising measuring aberrations at all field points of the measuring grid to generate measured aberration data;
defining an auxiliary grid comprising a second subset of target field points of the plurality of target field points comprising selected target field points of the plurality of field points not included in the measuring grid for which a level of aberration is to be determined in an aberration data generating operation; and
performing the aberration data generating operation, wherein the aberration data generating operation is configured to generate aberration data for target field points of the auxiliary grid based on
(i) knowledge of the optical imaging system and
(ii) potential system-specific sources of aberrations.

2. The method of claim 1, wherein
the aberration data generating operation comprises:
reconstructing at least one perturbation of at least one optical element of the optical imaging system consistent with an aberration fingerprint determined based on the measured aberration data in the measuring grid; and
executing a forward calculation based on the at least one perturbation obtained in the reconstructing to determine field aberration data for all field points in the target grid.

3. The method of claim 2, wherein
the reconstructing comprises setting a refractive index of interspaces between optical surfaces of the optical imaging system to a value 1.

4. The method of claim 1, wherein
the knowledge of the optical imaging system comprises design data representing a specification of a nominal optical design of the optical imaging system, the design data comprising, for each optical surface of the optical imaging system, at least one of:
surface figure data representing a nominal surface figure according to the specification,
distance data representing a distance between the optical surface and neighboring optical surfaces,
size data representing a size of a portion of the optical surface actually used when the optical system is used; or
index data representing the optical nature of the optical surface to distinguish between reflective surface and refractive surfaces.

5. The method of claim 4, wherein
knowledge of the optical imaging system comprises perturbation data, the perturbation data comprising sensitivity data representing, for each optical surface of the optical imaging system, a relation between a surface figure error representing a deviation of an optical surface from a nominal optical surface according to the specification and a contribution to a wavefront aberration caused by the surface figure error.

6. The method of claim 1, wherein
a mesh width of the measuring grid is set such that distances between target field points of the first subset are small enough such that sub-apertures associated with the target field points overlap and encompass an entire useful area on each optical surface of the optical imaging system.

7. A projection exposure apparatus comprising:
illumination system (ILL),
a projection lens (PO),
a measuring system (MES) configured to perform measurements of a wavefront of projection radiation passing in the projection lens from a mask to a substrate to be exposed in a spatially resolving measurement for a plurality of field points in an image field (IF) of the projection lens (PO);
a system configured to determine field-dependent aberrations in the image field (IF) of the projection lens based on a measuring operation determining aberration data for a plurality of field points in the image field, wherein the system is configured to determine field-dependent aberrations according to the method according to claim 1.

8. A method of producing a semiconductor device by optical lithography using an optical imaging system set up by a method according to claim 1.
